(19) United States
(12) Patent Application Publication
(10) Pub. No.: US 2005/0102827 A1
(43) Pub. Date: May 19, 2005

(54) Frame attaching process

(76) Inventors: Neng-Yu Tseng, Hsinchu County (TW); Da-Shuang Kuan, Hsinchu County (TW); Chia-Te Lin, Chiayi County (TW); Sheng-Lung Chen, Hsinchu (TW); Dylan Yu, Keelung City (TW)

Correspondence Address: J C PATENTS, INC., 4 VENTURE, SUITE 250, IRVINE, CA, 92618, US

(21) Appl. No.: 10/718,455

(22) Filed: Nov. 19, 2003

(30) Foreign Application Priority Data
Nov. 13, 2003 (TW) 92131756

(51) Int. Cl. H05K 3/36

(52) U.S. Cl. 29/832; 29/830

(57) ABSTRACT

A frame attaching process is described. The frame attaching process is adapted for attaching a transparent substrate to an active area of a chip using a frame, wherein the active area of the chip has a functional area. In the frame attaching process, the frame can be formed on the attaching surface of the transparent substrate or on the active area of the chip. Then, the attaching surface of the transparent substrate is attached to the active area of the chip using the frame under a negative pressure. Finally, the frame is solidified. Therefore, in the frame attaching process, the possibility of frame cracking can be reduced and the yield of the frame attaching process can be improved.

### CROSS-REFERENCE TO RELATED APPLICATION

This application claims the priority benefit of Taiwan application serial no. 92131756, filed Nov. 13, 2003.

### BACKGROUND OF THE INVENTION

1. Field of the Invention

The present invention relates to a frame attaching process, and more particularly to a process of attaching a transparent substrate to a chip using a frame under a negative pressure for reducing the possibility of frame from cracking.

2. Description of the Related Art

Different from the traditional packing technology for a single die, wafer-level package (WLP) technology is used to process a wafer instead of a die. Compared with the traditional package technology, WLP can process for many chips during one back-end process and reduce processing time and costs. It means that a wafer can be packaged after the front-end process has been finished in which devices and circuits are formed on the wafer. A wafer saw process is served to cut the packaged wafer into many chip packages. WLP follows the development of Chip-Scale Package (CSP) and can be applied to Flip-Chip (FC) package or another type of package.

Optical-electronic technology has been advanced and optical-electronic devices have been fabricated by using semiconductor process. Its advancement is also towards smaller size, higher integrity and multiple functions. The optical-electronic devices having been fabricated using semiconductor process include Charge-Coupled Device (CCD), CMOS Image Sensor (CIS), Solar Cell, Bio-Chip or other similar devices. As mentioned above, when WLP technology is applied thereto to substantially reduce the processing time and manufacturing costs.

Generally, an active area of an optical-electronic chip has a functional area serving for sensing, illuminating or other functions. In order to protect the functional area, a transparent substrate, such as a glass substrate, is attached to the functional area of active area of the chip using a frame. The functional area of active area of the chip is covered by the transparent substrate and the frame; therefore, a sealed space is formed and prevents moistures and particles from the sealed space.

Referring to FIGS. 1A-1C, a process of forming CMOS image sensor (CIS) chips according a conventional WLP technology is shown. As shown in FIG. 1A, a glass substrate 110 and a CMOS image sensor (CIS) chip 120 are provided. The glass substrate 110 has an attaching surface 112 and the CIS chip 120 is one of chips within an un-sawed wafer (not shown). In addition, the CIS chip 120 has an active area 122 and the active area 122 has a sensing area 122a thereon.

As shown in FIG. 1B, a frame 130 is formed on the active area 122 of the CIS chip 120, and the frame 130 surrounds the sensing area 122a. As shown in FIG. 1C, the attaching surface 112 of the glass substrate 110 is attached to the frame formed on the active area 122 of the chip 120.

Referring to FIGS. 1C and 2, FIG. 2 is the top view showing the CIS chip after package. In order to clarify the issue of frame cracking, the glass substrate 110 is not shown in FIG. 2. It should be noted that the sealed space is formed and a pressure therein is increased because of the attaching process for glass substrate 110 and CIS chip 120. However, when the pressure difference between inside and outside of the sealed space is so large that the frame 130 is easy to crack.

The conventional frame attaching process is performed under atmosphere to attach the glass substrate to the chip. Because of the pressure difference between inside and outside of the sealed space, the phenomenon of frame cracking easily occurs. Therefore, a sealed space cannot be formed on the active area of the optical-electronic chip, and moistures and particles enter into the sealed space and adversely affect the normal operation of the chip.

### SUMMARY OF THE INVENTION

Therefore, one object of the present invention is to provide a frame attaching process for reducing the possibility of frame cracking when the transparent substrate is attached to the chip and thereby increase the yield.

In accordance with the object of the present invention described above, the present invention provides a frame attaching process adapted to attach an attaching surface of a transparent substrate to an active area of a chip using a frame, wherein the active area of the chip further comprises a functional area. The frame attaching process comprises: forming the frame on the active area of the chip, wherein the frame surrounds the functional area; attaching the attaching surface of the transparent substrate to the frame formed on the active area of the chip under a negative pressure; and solidifying the frame.

The present invention further provides a frame attaching process adapted to attach an attaching surface of a transparent substrate to an active area of a chip using a frame, wherein the active area of the chip further comprising a functional area. The frame attaching process comprises: forming a frame on the attaching surface of the transparent substrate; attaching the frame formed on the attaching surface of the transparent substrate to the active area of the chip under a negative pressure, the frame surrounding the functional area; and solidifying the frame.

According to the frame attaching process of the present invention, the negative pressure is from about 0.5 to about 0.9 atmospheres. In addition, the method of solidifying the frame is accomplished by exposing the frame to an ultraviolet light.

According to the present invention, a frame may be formed on the attaching surface of the substrate or the active area of the chip and then attach the attaching surface of the substrate to the active area of the chip using the frame under a negative pressure. Because the pressure difference between the inside and outside of the frame is reduced, the possibility of frame cracking is reduced and the yield of frame attaching process is improved.

In order to make the aforementioned and other objects, features and advantages of the present invention understandable, a preferred embodiment accompanied with figures is described in detail below.

### BRIEF DESCRIPTION OF THE DRAWINGS

FIGS. 1A-1C are schematic view illustrating the progression of steps of a process of forming a CMOS image sensor chips (CIS) according to a conventional WLP technology.

FIG. 2 is a top view showing the conventional CIS chip after package.

FIGS. 3A-3D are schematic views illustrating the progression of steps of a first exemplary frame attaching process in accordance with the present invention.

FIGS. 4A-4D are schematic views illustrating the progression of steps of a second exemplary frame attaching process in accordance with the present invention.

FIG. 5 is a top view showing the package structure of FIGS. 3D and 4D.

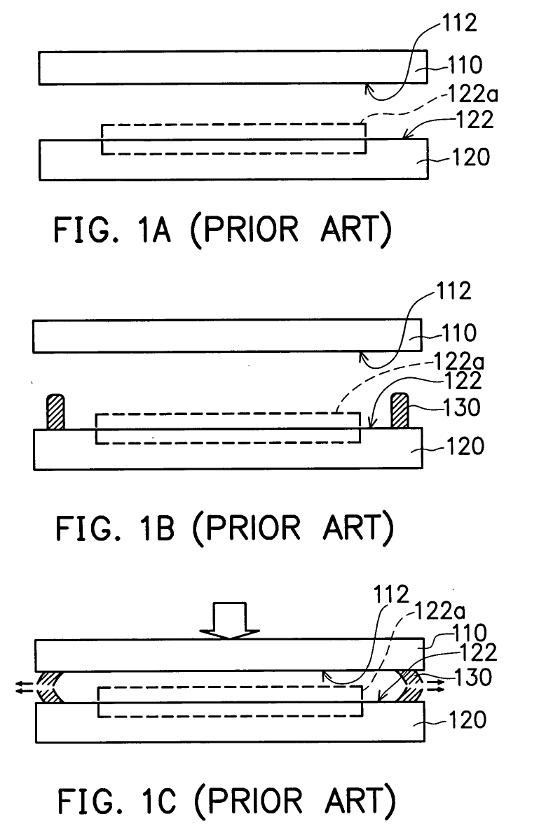

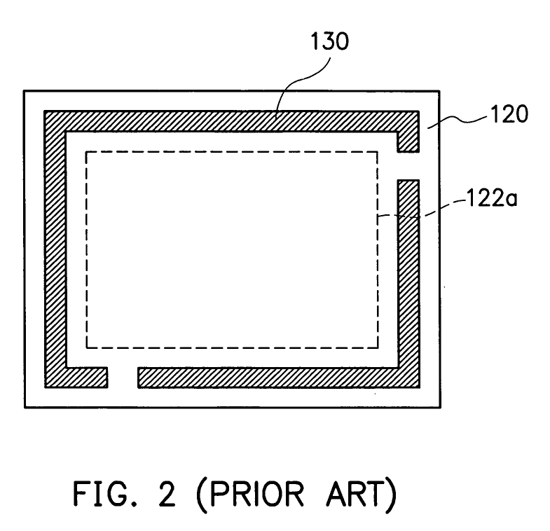

### DESCRIPTION OF SOME EMBODIMENTS

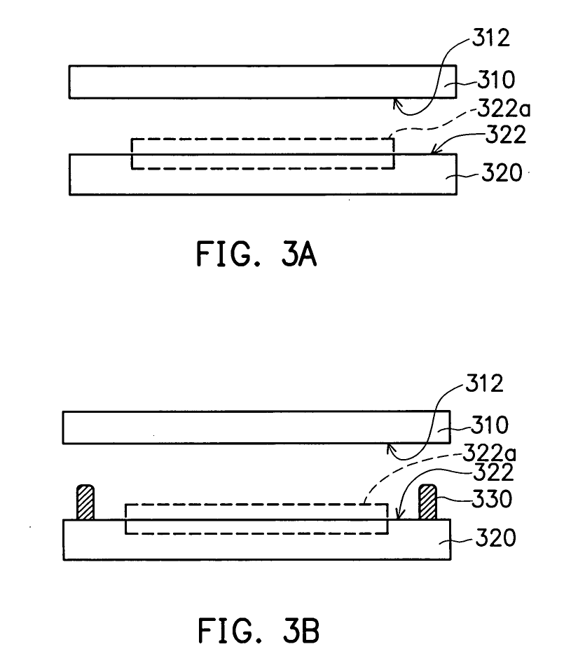

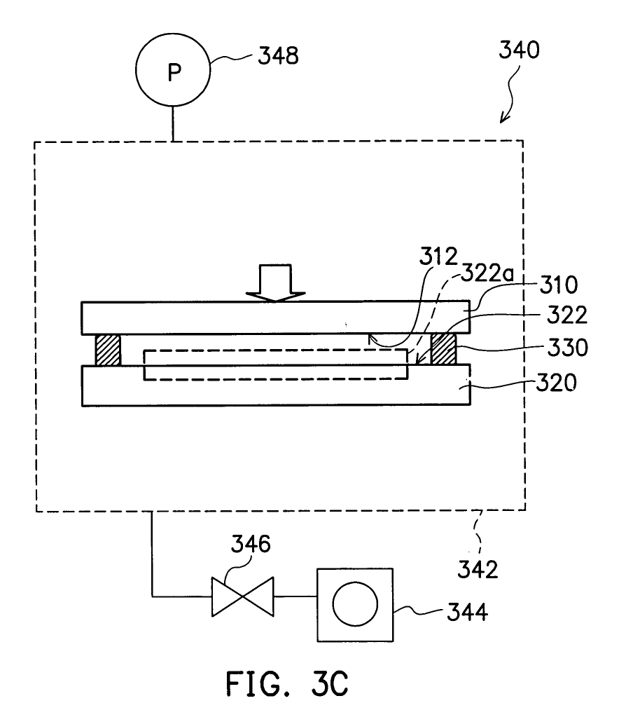

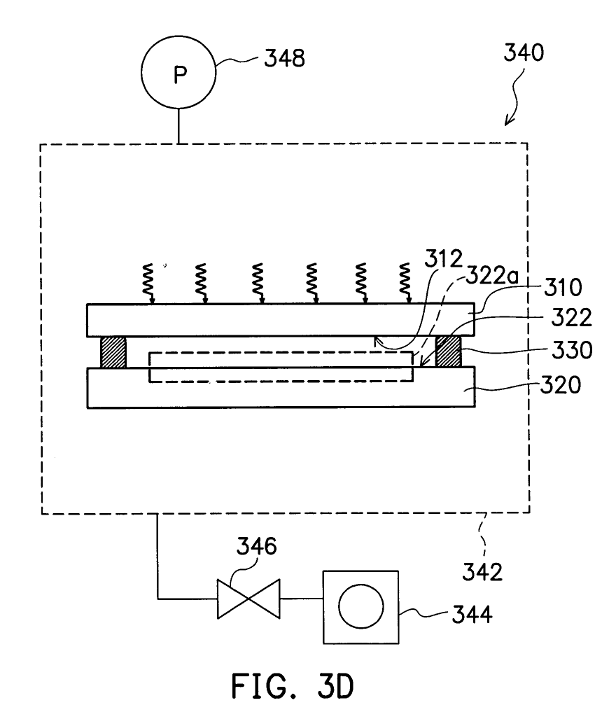

Please referring to FIGS. 3A-3D, they are a schematic process flow showing a first exemplary frame attaching process in accordance with the present invention.

As shown in FIG. 3A, a transparent substrate 310 and a chip 320 are provided. The transparent substrate 310 has an attaching surface 312 and the transparent substrate 310 can be made of, for example, glass or the other transparent material. The chip 320 is one of chips within an un-sawed wafer. In addition, each chip 320 has an active area 322 and the active area 322 has a functional area 322a thereon. When chip 320 is a chip with optical-electronic function, the functional area 322a can sense light or illuminate.

As shown in FIG. 3B, a frame 330 is formed on the active area 322 of the chip 320, and the frame 330 surrounds the functional area 322a.

As shown in FIG. 3C, a negative pressure is provided, which ranges from about 0.5 to about 0.9 atmospheres. The negative pressure is generated from, for example, a vacuum system. The vacuum system includes a chamber 342, a vacuum pump 344, a valve 346 and a pressure meter 348. The vacuum pump 344 serves to generate the negative pressure from about 0.5 to about 0.9 atmospheres. Moreover, the transparent substrate 310 and the chip 320 are moved in the chamber 342 and the attaching surface 312 of the transparent substrate 310 is attached to the frame 330 formed on the active area 322 of the chip 320 under the negative pressure.

As shown in FIG. 3D, the frame 330 is solidified, wherein the method of solidifying the frame is accomplished by exposing the frame 330 to an ultraviolet light or by using some other methods.

In addition to the first frame attaching process, the present invention discloses a second frame attaching process in which the difference between the first and second processes is that instead of forming the frame on the chip as described in the first frame attaching process, the frame is formed on the transparent substrate for attaching to the chip.

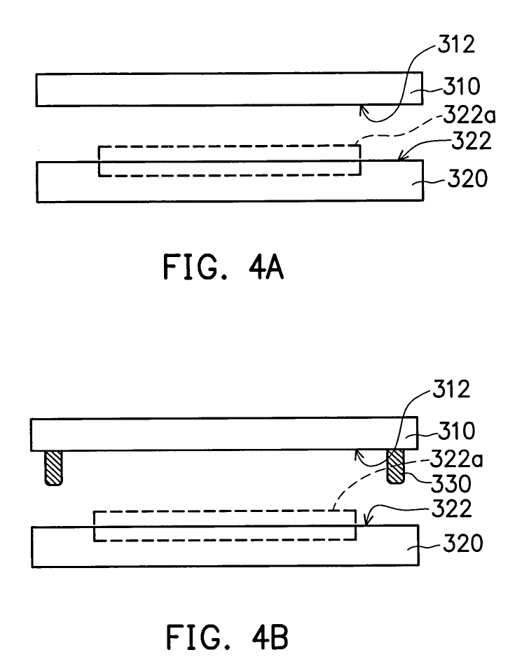

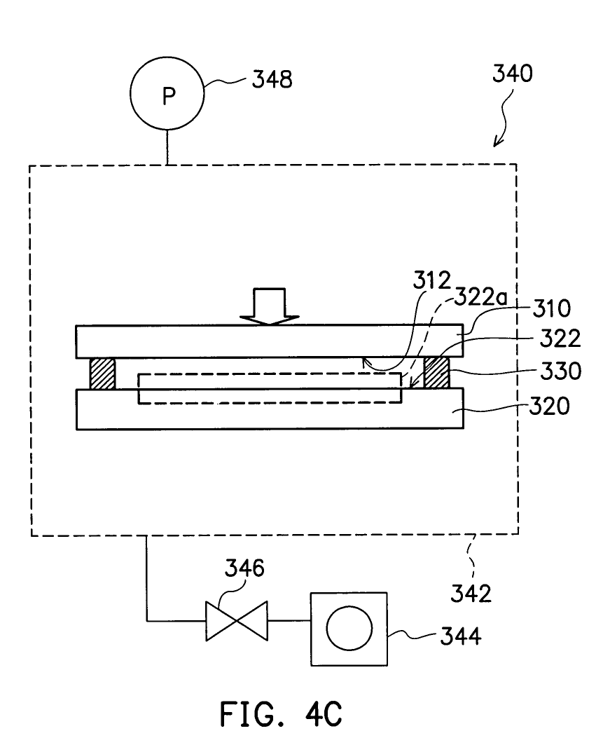

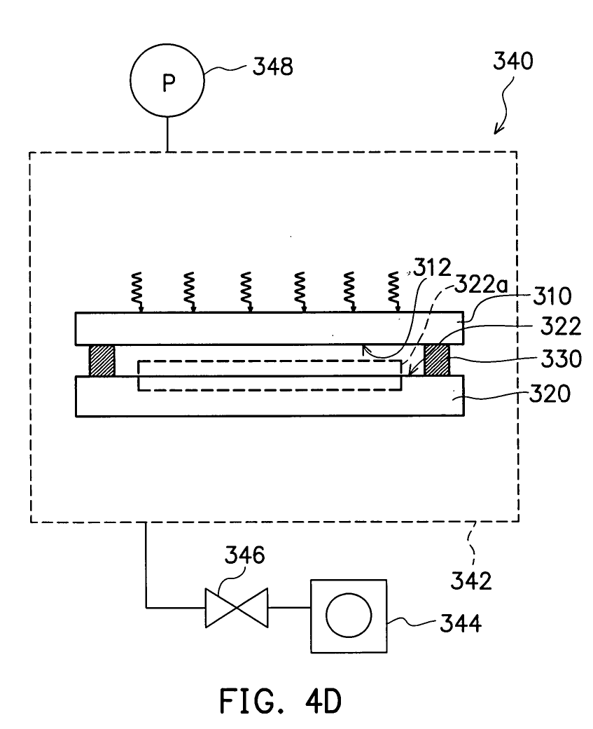

Referring to FIGS. 4A-4D, are a schematic views illustrating a second exemplary frame attaching process in accordance with the present invention.

As shown in FIG. 4A, a transparent substrate 310 and a chip 320 are provided. The descriptions of transparent substrate 310 and the chip 320 are the same described in the first frame attaching process and therefore is not repeated herein.

As shown in FIG. 4B, a frame 330 is formed on the attaching surface 312 of the transparent substrate 310 and corresponds to the perimeter of the active area 322 of the chip 320.

As shown in FIG. 4C, the transparent substrate 310 and the chip 320 are moved in the vacuum system 340, wherein the vacuum pump 344 serves to generate the negative pressure from about 0.5 to about 0.9 atmosphere in the chamber 342. Moreover, the transparent substrate 310 and the chip 320 are moved in the chamber 342 and the frame formed on the attaching surface 312 of the transparent substrate 310 is attached to the active area 322 of the chip 320.

As shown in FIG. 4D, the frame 330 is solidified, wherein the method of solidifying the frame is accomplished by exposing the frame 330 to an ultraviolet light or by using some other methods.

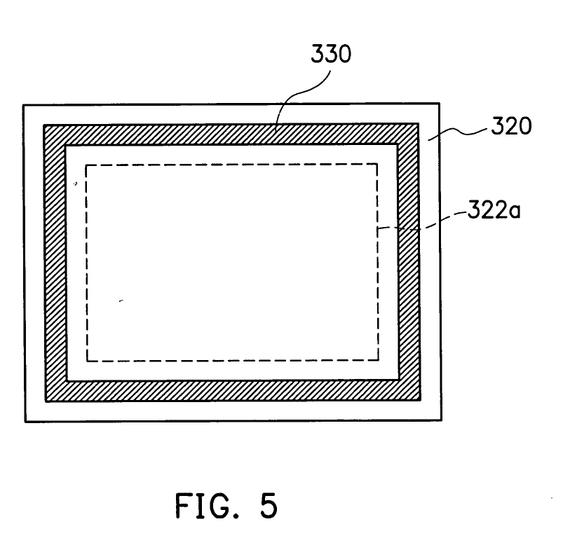

Referring to FIGS. 3D, 4D and 5, FIG. 5 is a top view showing the package structure of FIGS. 3D and 4D. In order to describe the position of the frame 330, the transparent substrate 310 shown in FIGS. 3D and 4D is not shown. It should be noted that although a higher pressure exists within a sealed space formed by the transparent substrate 310, the chip 320 and the frame 330 than outside of the chamber caused by attaching the transparent substrate 310 the chip 320, the frame cracking could barely occur because the chamber pressure was maintained in a negative pressure ranging between about 0.5 to about 0.9 atmosphere during the frame attaching process.

From the descriptions mentioned above, in the frame attaching process, the attaching surface of the transparent substrate is attached to the frame formed on the active area of the chip under a negative pressure and that the frame surrounds the functional area. It is to be noted that the frame can be formed on either on the attaching surface of the transparent substrate or on the active area of the chip. In the frame attaching process of the present invention, because the pressure within the sealed space where the transparent substrate, the chip and the frame are attached is low, and therefore the pressure difference between the inside and outside of the sealed frame is reduced. Therefore, the possibility of frame cracking is reduced and the yield of frame attaching process is improved.

In addition, the frame attaching process of the present invention can be applied to Charge-Coupled Device (CCD), CMOS Image Sensor (CIS), solar cells, Bio-chips and the other optical-electronic devices, so that the possibility of frame cracking thereof can be effectively reduced and thereby improve the yield of frame attaching process.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A frame attaching process adapted to attach an attaching surface of a transparent substrate to an active area of a chip by a frame, the active area of the chip comprising a functional area, the frame attaching process comprising:
forming the frame on the active area of the chip, the frame surrounding the functional area;
attaching the attaching surface of the transparent substrate to the frame formed on the active area of the chip under a negative pressure; and
solidifying the frame.

2. The frame attaching process of claim 1, wherein the negative pressure ranges from about 0.5 to about 0.9 atmospheres.

3. The frame attaching process of claim 1, wherein the step of solidifying the frame is performed by exposing the frame to an ultraviolet light.

4. A frame attaching process adapted to attach an attaching surface of a transparent substrate to an active area of a chip using a frame, the active area of the chip comprising a functional area, the frame attaching process comprising:
forming the frame on the attaching surface of the transparent substrate;
attaching the frame formed on the attaching surface of the transparent substrate to the active area of the chip under a negative pressure, the frame surrounding the functional area; and
solidifying the frame.

5. The frame attaching process of claim 4, wherein the negative pressure ranges from about 0.5 to about 0.9 atmospheres.

6. The frame attaching process of claim 4, wherein the step of solidifying the frame is performed by exposing the frame to an ultraviolet light.

7. A frame attaching process adapted to attach an attaching surface of a transparent substrate to an active area of a chip using a frame, the active area of the chip comprising a functional area, the frame attaching process comprising:
attaching the attaching surface of the transparent substrate to the active area of the chip using the frame under a negative pressure, the frame surrounding the functional area; and
solidifying the frame.

8. The frame attaching process of claim 7, further comprising forming the frame on the active area of the chip before the step of attaching the transparent substrate to the active area of the chip.

9. The frame attaching process of claim 7, further comprising forming the frame on the attaching surface of the transparent substrate before the step of attaching the transparent substrate to the active area of the chip.

10. The frame attaching process of claim 7, wherein the negative pressure ranges from about 0.5 to about 0.9 atmospheres.

11. The frame attaching process of claim 7, wherein the step of solidifying the frame is performed by exposing the frame to an ultraviolet light.
